(19) United States
(12) Patent Application Publication
(10) Pub. No.: US 2013/0092987 A1
(43) Pub. Date: Apr. 18, 2013

(54) MOS TRANSISTOR WITH NO HUMP EFFECT

(71) Applicant: STMICROELECTRONICS (ROUSSET) SAS, Rousset (FR)

(72) Inventor: Laurent Lopez, Rousset (FR)

(73) Assignee: STMICROELECTRONICS (ROUSSET) SAS, Rousset (FR)

(21) Appl. No.: 13/649,972

(22) Filed: Oct. 11, 2012

(30) Foreign Application Priority Data
Oct. 13, 2011 (FR) 1159242

(51) Int. Cl. H01L 29/78; H01L 21/336

(52) U.S. Cl. 257/288; 438/306; 257/E29.255; 257/E21.409

(57) ABSTRACT

A MOS transistor formed in an active area of a semiconductor substrate and having a polysilicon gate doped according to a first conductivity type, the gate including two lateral regions of the second conductivity type.

### BACKGROUND

1. Technical Field

The present disclosure relates to a MOS transistor, and more specifically to a MOS transistor intended to be used in analog applications, that is, a MOS transistor having a gate with a width and length much larger than the minimum dimensions of the used technology.

2. Description of the Related Art

In integrated circuits used for analog applications, MOS transistors are biased to operate at voltages lower than their threshold voltage. A parasitic effect then adversely affects MOS transistor characteristics. This effect, called “Hump effect”, is especially responsible for an increase in the off-state current (I_{OFF}) of MOS transistors, under certain biasing conditions.

FIG. 1A is a top view schematically showing a MOS transistor. FIG. 1B is a cross-section view along plane BB of FIG. 1A.

In a semiconductor substrate 1, for example, a silicon substrate, insulating trenches 3 surround the transistor, which is defined, in the top view of FIG. 1A, by an active area 5, having a width W₀ and a length L₀. Insulating trenches 3 for example are narrow and shallow trenches, for example, filled with silicon oxide, as commonly designated as STI (“Shallow Trench Insulation”) and used to isolate and separate transistors in a semiconductor substrate. Active area 5 is partially covered with a doped polysilicon gate 9, insulated by a gate insulator 7. Length L of the gate is smaller than length L₀ of the active area. Regions 6 of the active area which are not covered by the gate and which are located above and below the MOS transistor source and drain regions, as viewed in FIG. 1A. The carriers are transported in the gate length direction. In the gate width direction, the gate at least partly covers insulation trenches 3.

FIG. 1C is an enlargement of an area 11 of FIG. 1B, close to an edge of the active area. Each time the word “edge” or “lateral” is used herein, this word refers to regions located on the left-hand and right-hand sides of the particular element referred to, as viewed in the orientations of FIGS. 1A or 1B. Above the upper surface of the edge of active area 5, the thickness of gate insulator 7 may be decreased. Active area 5 may also have a significant radius of curvature on the edge. There may further exist a region 13 of the edge of active area 5, close to insulating trench 3, having a lower doping level than the rest of the active area.

Such phenomena result in the presence of parasitic MOS transistors having a threshold voltage smaller than the targeted threshold voltage, between the source and the drain of the MOS transistor and towards the edges thereof.

Thus, the real MOS transistor corresponds, as illustrated in FIG. 2, to a main MOS transistor 15 in parallel with two parasitic MOS transistors 17 and 19, having a lower threshold voltage than main MOS transistor 15. Drains D, sources S, and gates G of these three transistors are common. The locations of main MOS transistor 15 and of the two parasitic MOS transistors 17 and 19 are approximately delimited by dotted lines in FIGS. 1A and 1B.

FIG. 3 illustrates characteristics of drain current I_{D} versus gate voltage V_{G} of an N-channel MOS transistor, having a 1-μm gate length and a 10-μm gate width, for different positive voltages V_{SB} between substrate B and source S. Curve 21 corresponds to a zero voltage V_{SB}, and curves 23, 26, 29 correspond to increasingly high voltages V_{SB}.

Below the threshold voltage, curve 21 comprises a linear portion 22, which corresponds to theoretical characteristic I_{D}(V_{G}) of a MOS transistor. Curve 29, instead of having, below the threshold voltage, a linear portion 30 as shown in dotted lines, comprises a linear portion 31 shifted towards the lowest gate voltages. This shift, due to the conduction of parasitic MOS transistors 17 and 19 of lower threshold voltage than main MOS transistor 15, causes an increase in current I_{OFF} of the MOS transistor.

Curves 23 and 26 have shapes between those of curves 21 and 29 (the Hump effect increases along with voltage V_{SB}).

FIG. 4 illustrates characteristics I_{D}(V_{G}) of an N-channel MOS transistor and of a P-channel MOS transistor, for two substrate biasing values, the drain current and the gate voltage being plotted in absolute value to make the comparison between the characteristics of the N-channel and P-channel MOS transistors easier.

Curves 33 and 36 correspond to an N-channel MOS transistor, respectively for V_{SB}=0 and for V_{SB}=3.3 V. Curves 34 and 37 correspond to a P-channel MOS transistor, respectively for V_{SB}=0 and for V_{SB}=−3.3 V. It can be seen that the Hump effect especially appears for N-channel MOS transistors, which induces an off-state current difference between the N-channel and P-channel MOS transistors, and thus decreases the general performance of CMOS integrated circuits, and especially of analog circuits using biasings below the threshold.

To decrease the Hump effect, MOS transistors with active areas having specific shapes may be used. However, such MOS transistors use a semiconductor substrate surface area greater than that of conventional MOS transistors and may be unreliable.

### BRIEF SUMMARY

An embodiment provides a MOS transistor with no Hump effect, having the same surface area as a conventional MOS transistor.

An embodiment provides a method for manufacturing a MOS transistor with no Hump effect, the method not requiring an additional step with respect to methods currently used for the manufacturing of CMOS integrated circuits.

An embodiment provides a MOS transistor formed in an active area of a semiconductor substrate and having a polysilicon gate doped according to a first conductivity type, the gate comprising two lateral regions of the second conductivity type.

According to an embodiment, the two lateral regions have same dimensions and extend symmetrically on either side of the axis of symmetry of the active area in the gate length direction.

According to an embodiment, each of the two lateral regions is located above the center of a respective edge of the active area.

According to an embodiment, the MOS transistor has an N channel, and the gate is N-type doped, while the two regions are P-type doped.

According to an embodiment, the active area is surrounded with insulating trenches.

Another embodiment provides a method for manufacturing a MOS transistor in an active area of a semiconductor substrate, comprising the steps of: a) forming a polysilicon gate on the upper surface of the active area; b) implanting first dopants in the gate according to a first conductivity type, except in two lateral regions; and c) implanting second dopant elements in the two regions according to the second conductivity type.

According to an embodiment, the two regions have same dimensions and are formed symmetrically on either side of the axis of symmetry of the active area in the gate length direction.

According to an embodiment, each region is formed above the center of an edge of the active area.

According to an embodiment, the gate is N-type doped and the two regions are P-type doped.

According to an embodiment, the method further comprises: at step b), an implantation of source and drain regions; and at step c), an implantation of an area intended to be connected to a device for biasing the substrate.

The foregoing and other features and advantages will be discussed in detail in the following non-limiting description of specific embodiments in connection with the accompanying drawings.

### BRIEF DESCRIPTION OF THE SEVERAL VIEWS OF THE DRAWINGS

FIGS. 1A and 1B, previously described, respectively are top and cross-section views schematically showing a known MOS transistor;

FIG. 1C, previously described, is an enlargement of an area of FIG. 1B indicated at 11;

FIG. 2, previously described, shows an equivalent electric diagram of a MOS transistor submitted to the Hump effect;

FIG. 3, previously described, shows characteristics I_{D}(V_{G}) of the drain current versus the gate voltage of a known N-channel MOS transistor, for different voltages between the substrate and the source;

FIG. 4, previously described, illustrates characteristics I_{D}(V_{G}) of an N-channel MOS transistor and of a P-channel MOS transistor, for two substrate biasing values;

FIG. 5A is a top view schematically showing a MOS transistor with no Hump effect, and FIGS. 5B and 5C are cross-section views corresponding to FIG. 5A; and

FIG. 6 shows an equivalent electric diagram of a MOS transistor with no Hump effect.

For clarity, the same elements have been designated with the same reference numerals in the different drawings and, further, as usual in the representation of integrated circuits, the various drawings are not to scale.

### DETAILED DESCRIPTION

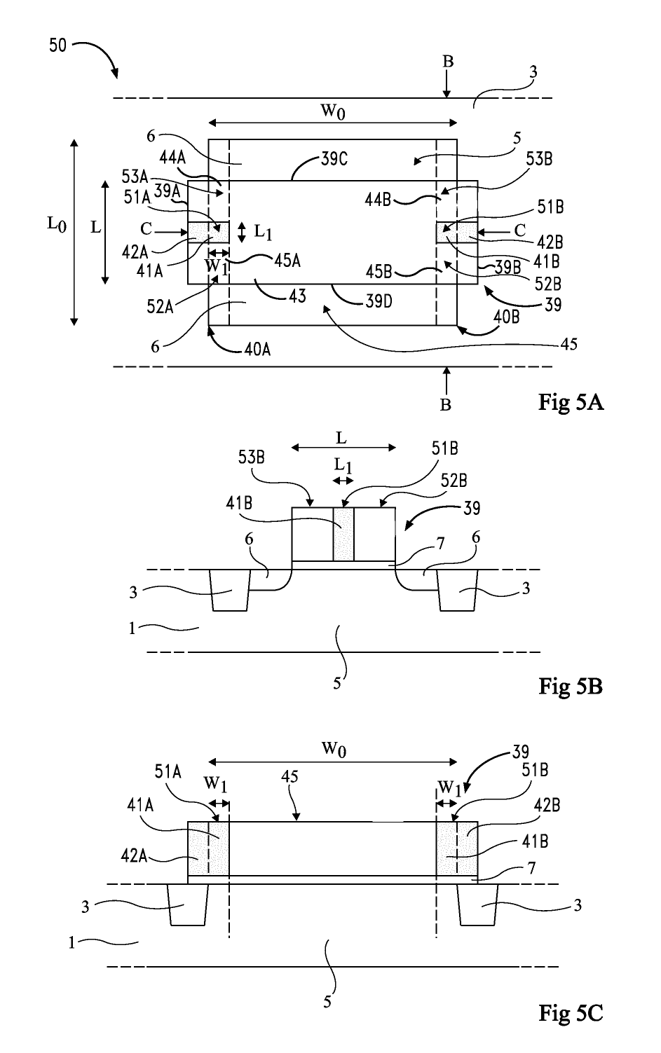

FIG. 5A is a top view of a MOS transistor device 50 with no Hump effect. FIGS. 5B and 5C are cross-section views along planes BB and CC of FIG. 5A, respectively.

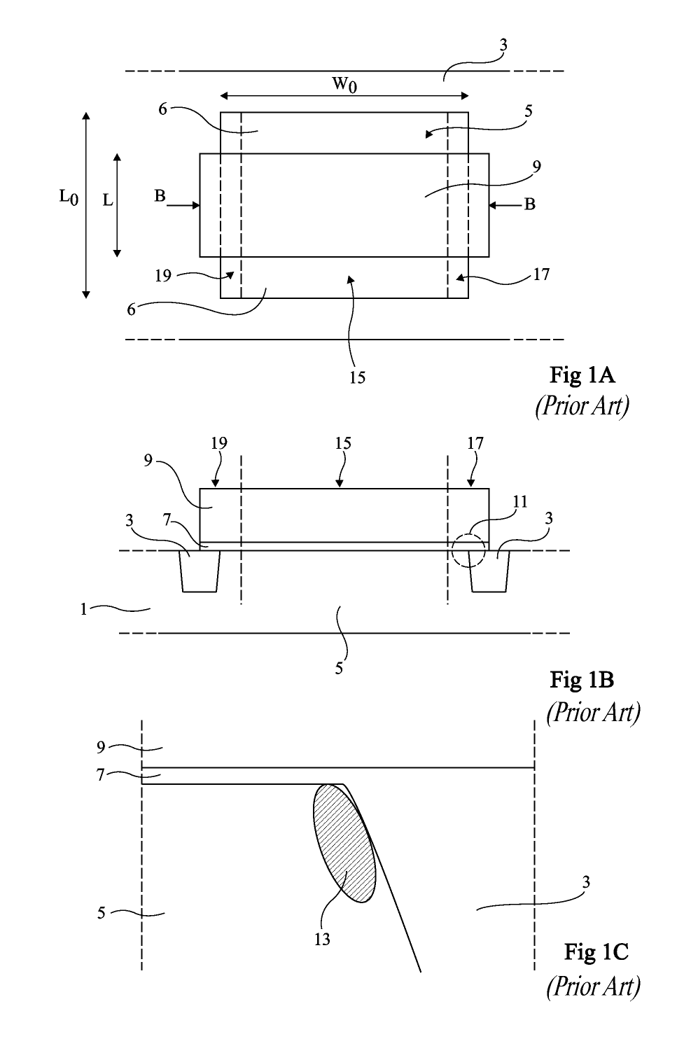

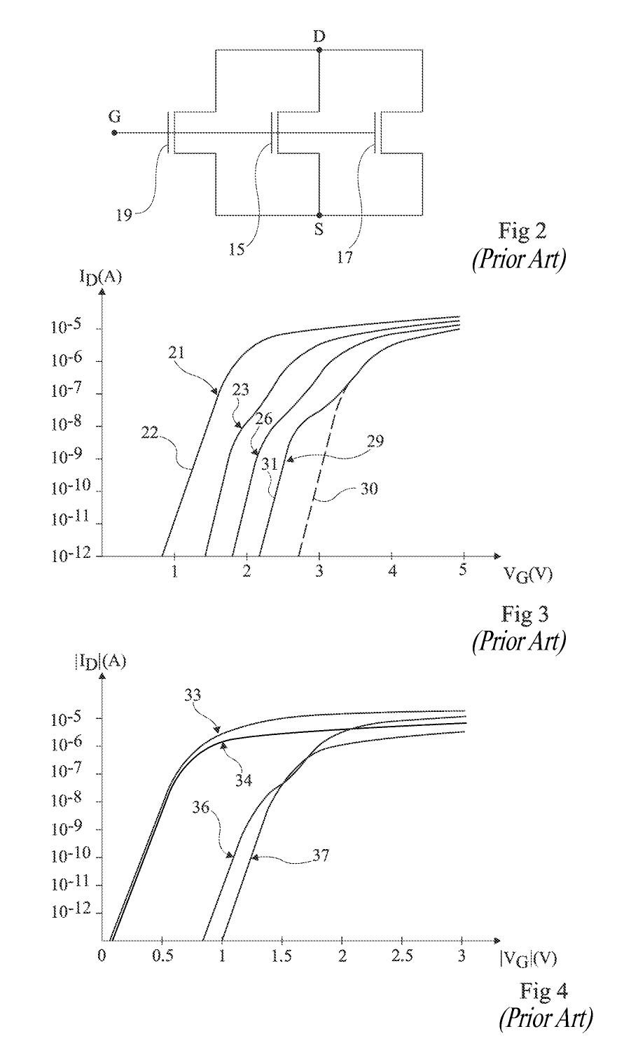

FIG. 5A is similar to FIG. 1A. The elements of FIG. 5A common with those of FIG. 1A have been designated with the same reference numerals and are not described again.

The MOS transistor device 50 includes a gate 39, preferably made of polysilicon, that is doped, at the same time as the source and drain regions of the concerned MOS transistor device in one embodiment. The gate 39 includes first, second, third, and fourth edges 39A, 39B, 39C, 39D and a main portion 43 doped according to a first conductivity type. To suppress the Hump effect, the gate 39 includes, respectively above first and second edges 40A, 40B of active area 5, respective regions 41A, 41B doped according to the conductivity type opposite to that of the main portion 43 of the gate.

The gate 39 further includes regions 44A, 45A above the first edge 40A and on opposite sides of the region 41A, and regions 44B, 45B above the second edge 40B and on opposite sides of the region 41B. The regions 44A, 44B and 45A, 45B are all doped according to the same conductivity type as the main portion 43 of the gate 39. The region 44A is between the third gate edge 39C and the region 41A, the region 45A is between the fourth gate edge 39D and the region 41A, the region 44B is between the third gate edge 39C and the region 41B, and the region 45B is between the fourth gate edge 39D and the region 41B.

In the example of FIGS. 5A to 5C, the two regions 41A, 41B have same dimensions, that is, width W₁ in the gate width direction and length L₁ in the gate length direction. Each region 41A, 41B is located above a respective central region, in the length direction L, of the corresponding edge 40A, 40B of active area 5. Regions 41A, 41B may also be located anywhere above the edges of active area 5, for example, symmetrically with respect to the axis of symmetry of the active area in the gate length direction. Regions 41A, 41B may also have neither the same width W₁ nor the same length L₁. In practice, useless regions 42A, 42B of the gate, adjacent to region 41 and above insulating trenches 3, are doped with the same conductivity type and the same doping level as regions 41A, 41B. The regions 41A, 42A are positioned between the main portion 43 and the first edge 39A of the gate 39 and the regions 41B, 42B are positioned between the main portion 43 and the second edge 39B of the gate 39.

As an example of orders of magnitude, for a gate having a length L of approximately 1 μm and a width W₀ of approximately 10 μm, length L₁ of regions 41 is approximately 300 nm and their width W₁ is approximately 200 nm. In general, the length of the regions 41 is less than about one third of the length of the gate, and the width of each of the regions is less than about one tenth of the width of the gate.

In the case of an N-channel MOS transistor, polysilicon gate 39 is generally heavily N-type doped, for example, with a doping level ranging from 10¹⁸ to 10²⁰ atoms/cm³, like source and drain regions 6. To suppress the Hump effect, regions 41A, 41B of gate 39 are then P-type doped with a doping level of the same order of magnitude as the main gate portion.

Thus, between the source and the drain of the MOS transistor device 50 and along the respective edges 40A, 40B of the gate 39, are respective parasitic MOS transistors 47, 49 each having a gate length L₁ and a gate width W₁, and having a threshold voltage much greater, and no longer smaller, than the targeted threshold voltage.

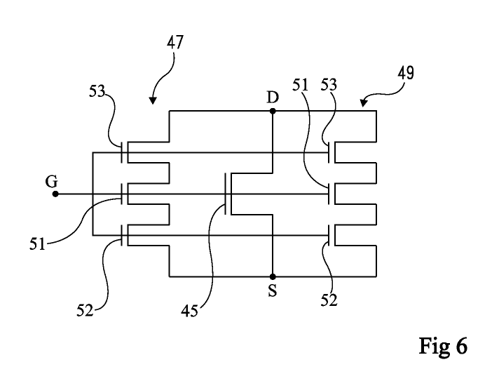

The MOS transistor device 50 described in relation with FIGS. 5A to 5C corresponds, as illustrated in FIG. 6, includes a main MOS transistor 45, in parallel with the two parasitic MOS transistors 47 and 49. Each parasitic MOS transistor 47 and 49 is actually formed of a series connection of three transistors: a transistor 52A, 52B having a threshold voltage smaller than the targeted threshold voltage, a transistor 51A, 51B having a threshold voltage much greater than the targeted threshold voltage, and a transistor 53A, 53B having a threshold voltage smaller than the targeted threshold voltage. The resulting threshold voltage of parasitic MOS transistors 47 and 49 thus is that of MOS transistors 51, which is greater than the targeted threshold voltage.

The transistors 51A, 52A, 53A of the MOS transistor 47 share source and drain regions formed by portions of the source and drain regions 6 of the MOS transistor device 50 and have respective gates formed by the gate regions 41A, 44A, 45B, respectively. Similarly, the transistors 51B, 52B, 53B of the MOS transistor 49 share source and drain regions formed by portions of the source and drain regions 6 of the MOS transistor device 50 and have respective gates formed by the gate regions 41B, 44B, 45B, respectively.

The locations of main MOS transistor 45 and of the MOS transistors 51, 52, and 53 are approximately delimited by dotted lines in FIGS. 5A to 5C.

An advantage of a MOS transistor such as that described in relation with FIGS. 5A to 5C is that it has the same surface area as a conventional MOS transistor.

A method for manufacturing a MOS transistor of the type described in relation with FIGS. 5A to 5C comprises the following steps.

The polysilicon gate 39, insulated by the gate insulator 7, is formed above the upper surface of the active area 5 of the semiconductor substrate 1, for example, a silicon substrate.

Once gate 39 has been formed, dopant elements are implanted in gate 39 according to one or the other of the conductivity types, except in the two regions 41A, 41B.

The implantation of dopant elements in the polysilicon gate is carried out simultaneously to the implantation of dopant elements in active area 5, on either side of the gate, to form source and drain regions 6 of the MOS transistor. Thus, in the case of an N-channel MOS transistor, the polysilicon gate is generally heavily N-type doped, like the source and drain regions. Conversely, in the case of a P-channel MOS transistor, the polysilicon gate is generally heavily P-type doped like the source and drain regions.

Then, in regions 41A, 41B, dopant elements are implanted according to the conductivity type opposite to that of the main portion 43 of the gate 39. To carry out this dopant element implantation step, a mask complementary to the mask previously used to protect regions 41A, 41B from the first implantation is for example used.

During a MOS transistor manufacturing process, a mask is currently used for the implantation of the source, drain, and gate regions to protect substrate regions which are desired to be implanted with the other conductivity type, like for example an area intended to be connected to a substrate-biasing device. To manufacture a MOS transistor of the type described in relation with FIGS. 5A to 5C, it is thus sufficient to slightly modify this mask to protect regions 41A, 41B from the first implantation. Further, two successive steps of implantation of dopant elements according to one, and then the other, of the two conductivity types, are already used in a conventional MOS transistor manufacturing process. A method for manufacturing a MOS transistor of the type described in relation with FIGS. 5A to 5C thus does not require an additional step with respect to a method currently used for the manufacturing of a MOS transistor.

Specific embodiments of the present disclosure have been described. Various alterations, modifications, and improvements will readily occur to those skilled in the art. In particular, although an embodiment for an N-channel MOS transistor has been described, the present disclosure of course also applies to a P-channel MOS transistor. In such an embodiment, the main portion 43 of the gate is P-type doped, and regions 41A, 41B are N-type doped.

Such alterations, modifications, and improvements are intended to be part of this disclosure, and are intended to be within the spirit and the scope of the present disclosure. Accordingly, the foregoing description is by way of example only and is not intended to be limiting.

The various embodiments described above can be combined to provide further embodiments. These and other changes can be made to the embodiments in light of the above-detailed description. In general, in the following claims, the terms used should not be construed to limit the claims to the specific embodiments disclosed in the specification, but should be construed to include all possible embodiments along with the full scope of equivalents to which such claims are entitled. Accordingly, the claims are not limited by the disclosure.

1. A device, comprising:
a semiconductor substrate;
an active area defined in the semiconductor substrate, the active area having first and second edges opposite to each other; and
a gate positioned on the semiconductor substrate over the active area, the gate having first and second edges that extend transversely with respect to the first and second edges of the active area and are on opposite sides of the gate, a central region doped according to a first conductivity type, and first and second lateral regions doped according to a second conductivity type and spaced apart from each other by the central region, the first and second lateral regions being spaced apart from the first and second edges of the of the gate.

2. The device of claim 1, wherein the two lateral regions have same dimensions and extend symmetrically on either side of an axis of symmetry of the active area in a direction transverse to the first and second edges of the gate.

3. The device of claim 2, wherein the gate includes:
third and fourth lateral regions positioned above the first edge of the active area and doped according to the first conductivity type, the third lateral region being positioned between the first lateral region and the first edge of the gate and the fourth lateral region being positioned between the first lateral region and the second edge of the gate; and
fifth and sixth lateral regions positioned above the second edge of the active area and doped according to the first conductivity type, the fifth lateral region being positioned between the second lateral region and the first edge of the gate and the sixth lateral region being positioned between the second lateral region and the second edge of the gate.

4. The device of claim 1 wherein the first conductivity type is N and the second conductivity type is P.

5. The device of claim 1, wherein the active area is surrounded with and delimited by insulating trenches.

6. The device of claim 5, wherein the gate includes:
third and fourth edges extending between the first and second edges of the gate;
a third lateral region contiguous with the first lateral region, extending between the first lateral region and the third edge, and doped according to the second conductivity type; and
a fourth lateral region contiguous with the second lateral region, extending between the second lateral region and the fourth edge, and doped according to the second conductivity type.

7. A method, comprising:
manufacturing a MOS transistor in an active area of a semiconductor substrate, the active area having first and second edges opposite to each other, the manufacturing including:
forming a gate on a surface of the active area, the gate having first and second edges that extend transversely with respect to the first and second edges of the active area and are on opposite sides of the gate;
implanting first dopant elements in a central region of the gate according to a first conductivity type; and
implanting second dopant elements in first and second lateral regions of the gate according to a second conductivity type, the lateral regions being spaced apart from each other by the central regions, the first and second lateral regions being spaced apart from the first and second edges of the of the gate.

8. The method of claim 7, wherein the first and second lateral regions have same dimensions and are formed symmetrically on either side of a axis of symmetry of the active area in a direction transverse to the first and second edges of the gate.

9. The method of claim 8, comprising:
implanting the first dopant elements according to a first conductivity type in third and fourth lateral regions above the first edge of the active area, the third lateral region being positioned between the first lateral region and the first edge of the gate and the fourth lateral region being positioned between the first lateral region and the second edge of the gate; and
implanting the first dopant elements according to a first conductivity type in fifth and sixth lateral regions positioned above the second edge of the active area, the fifth lateral region being positioned between the second lateral region and the first edge of the gate and the sixth lateral region being positioned between the second lateral region and the second edge of the gate.

10. The method of claim 7, wherein the first conductivity type is N and the second conductivity type is P.

11. The method of claim 7 wherein:
implanting the first dopant elements includes implanting the first dopant elements in source and drain regions of the active area according to the first conductivity type; and
implanting the second dopant elements includes implanting the second dopant elements in a portion of the active area configured to be connected to a device for biasing the substrate.

12. The method of claim 7, comprising forming insulating trenches delimiting the first and second edges of the active area, wherein:
the gate includes third and fourth edges extending between the first and second edges of the gate; and
implanting the second dopant elements includes:
implanting the second dopant elements in a third lateral region contiguous with the first lateral region and extending between the first lateral region and the third edge; and
implanting the second dopant elements in a fourth lateral region contiguous with the second lateral region and extending between the second lateral region and the fourth edge.

13. A MOS transistor, comprising:
a semiconductor substrate that includes a channel region and source and drain regions positioned at opposite first and second sides of the channel region and having a first type of conductivity;
a gate positioned over the channel region and including first and second edges that extend substantially parallel to the first and second sides of the channel region and are on opposite sides of the gate, a central region the first type of conductivity, and a first lateral region doped according to a second conductivity type and spaced apart from the first and second edges of the gate.

14. The transistor of claim 13, wherein the gate includes a second lateral region spaced apart from the first lateral region by the central region, spaced apart from the first and second edges of the gate, and having the second type of conductivity.

15. The transistor of claim 14, wherein the channel region includes third and fourth sides extending between the first and second sides of the channel region and the first and second lateral regions of the gate are centered along the third and fourth sides, respectively, of the channel region.

16. The transistor of claim 15, wherein the gate includes:
third and fourth lateral regions doped according to the first conductivity type, the third lateral region being positioned between the first lateral region and the first edge of the gate and the fourth lateral region being positioned between the first lateral region and the second edge of the gate; and
fifth and sixth lateral regions doped according to the first conductivity type, the fifth lateral region being positioned between the second lateral region and the first edge of the gate and the sixth lateral region being positioned between the second lateral region and the second edge of the gate.

17. The transistor of claim 15, wherein the third and fourth sides of the channel region are delimited by first and second insulating trenches, respectively.

18. The transistor of claim 15, wherein the gate includes:
third and fourth edges extending between the first and second edges of the gate;
a third lateral region contiguous with the first lateral region, extending between the first lateral region and the third edge, and doped according to the second conductivity type; and
a fourth lateral region contiguous with the second lateral region, extending between the second lateral region and the fourth edge, and doped according to the second conductivity type.

19. The transistor of claim 13, wherein the first conductivity type is P and the second conductivity type is N.
